(19) United States
(12) Patent Application Publication
(10) Pub. No.: US 2016/0072065 A1
(43) Pub. Date: Mar. 10, 2016

(54) DEPOSITION APPARATUS AND METHOD OF DEPOSITING THIN-FILM OF ORGANIC LIGHT-EMITTING DISPLAY DEVICE BY USING THE DEPOSITION APPARATUS

(71) Applicant: Samsung Display Co., Ltd., Yongin-city (KR)

(72) Inventors: Jaesik Kim, Yongin-City (KR); Hyunsung Bang, Yongin-City (KR); Duckjung Lee, Yongin-City (KR); Sungsoon Im, Yongin-City (KR); Youngsuk Cho, Yongin-City (KR); Kyuhwan Hwang, Yongin-City (KR)

(21) Appl. No.: 14/614,019

(22) Filed: Feb. 4, 2015

(30) Foreign Application Priority Data
Sep. 5, 2014 (KR) 10-2014-0119381

(51) Int. Cl. H01L 51/00; H01L 51/56; B05B 15/04

(52) U.S. Cl. CPC H01L 51/0011; B05B 15/045; H01L 51/0012; H01L 51/56

(57) ABSTRACT

Provided is a deposition apparatus including a deposition source including a plurality of nozzles that spray a deposition material onto a substrate; a mask disposed between the substrate and the deposition source and separated from the substrate, and including a plurality of first openings through which the deposition material passes; and at least one deposition incident angle adjusting plate disposed between the mask and the deposition source and including a plurality of second openings for adjusting a deposition incident angle of the deposition material that is sprayed from the plurality of nozzles; wherein the at least one deposition incident angle adjusting plate is movable in a first direction toward the substrate or a second direction opposite the first direction, and the deposition incident angle adjusting plate is spaced apart from the nozzles.

### CLAIM OF PRIORITY

This application claims the priority and all the benefits accruing under 35 U.S.C. §119 of Korean Patent Application No. 10-2014-0119381, filed on Sep. 5, 2014, in the Korean Intellectual Property Office (“KIPO”), the disclosure of which is incorporated herein in its entirety by reference.

### BACKGROUND OF THE INVENTION

1. Field of the Invention

One or more embodiments of the present invention relate to a deposition apparatus and a method of depositing a thin-film of an organic light-emitting display device by using the deposition apparatus.

2. Description of the Related Art

Among the display devices, organic light-emitting display devices have a wide viewing angle, excellent contrast ratio, and high response time, and thus, they have been regarded as the next-generation display devices.

In general, an organic light-emitting display device has a stack-type structure in which an emission layer is placed between an anode and a cathode emits lights of different colors by recombination of holes and electrons respectively inserted therein from the anode and the cathode. However, since it is difficult to obtain highly efficient emission based on this stack-type structure, one or more intermediate layers such as an electron injection layer, an electron transport layer, a hole transport layer, a hole injection layer, or the like are selectively placed between the electrodes and the emission layer.

A thin-film in the structure of the organic light-emitting display device is formed by using a vacuum deposition process whereby an organic material or metal to form an electrode is deposited on a substrate in a vacuum atmosphere. The vacuum deposition process is performed by placing a substrate on which an organic thin-film is to be formed in a vacuum chamber, adhering a fine metal mask (FMM) having the same pattern as the organic thin-film to the substrate, evaporating or sublimating the organic material by using a deposition source, and depositing the evaporated or sublimated organic material on the substrate.

### SUMMARY OF THE INVENTION

One or more embodiments of the present invention include a deposition apparatus and a method of depositing a thin-film of an organic light-emitting display device by using the deposition apparatus, whereby the thin-film is deposited on a substrate with improved uniformity.

Additional aspects will be set forth in part in the description which follows and, in part, will be apparent from the description, or may be learned by practice of the presented embodiments.

According to one or more embodiments of the present invention, a deposition apparatus includes a deposition source including a plurality of nozzles that spray a deposition material onto a substrate; a mask disposed between the substrate and the deposition source and including a plurality of first openings through which the deposition material passes; and at least one deposition incident angle adjusting plate disposed between the mask and the deposition source and including a plurality of second openings for adjusting a deposition incident angle of the deposition material that is sprayed from the plurality of nozzles, wherein the at least one deposition incident angle adjusting plate is movable in a first direction toward the substrate or a second direction opposite the first direction. The mask is separated from the substrate by a gap.

A distance between the substrate and the at least one deposition incident angle adjusting plate may vary according to a movement of the at least one deposition incident angle adjusting plate.

A distance between the deposition source and the at least one deposition incident angle adjusting plate may vary according to a movement of the at least one deposition incident angle adjusting plate.

The plurality of nozzles may be linearly arrayed in a direction that is perpendicular to the first direction.

The deposition source may be moved in a direction that is perpendicular to the first direction and may cross the direction in which the plurality of nozzles are arrayed.

The plurality of second openings may extend in a direction that is in parallel with a movement direction of the deposition source.

The plurality of second openings may extend in a direction that forms an acute angle with a movement direction of the deposition source.

According to one or more embodiments of the present invention, a method of depositing a thin-film of an organic light-emitting display device by using a deposition apparatus includes operations of disposing a substrate to face a deposition source including a plurality of nozzles that spray a deposition material; depositing the deposition material, which are sprayed from the plurality of nozzles, on the substrate via a plurality of second openings of a deposition incident angle adjusting plate and a plurality of first openings of a mask; and moving the deposition incident angle adjusting plate in at least one of a first direction toward the substrate and a second direction opposite the first direction.

One or more regions of the substrate on which the deposition material is deposited may vary according to a movement of the deposition incident angle adjusting plate.

The deposition material may include an organic material for forming an organic emission layer. The deposition material may also include a metal material.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a deposition apparatus according to an embodiment of the present invention;

FIG. 2 illustrates the deposition apparatus of FIG. 1, FIG. 2A illustrates the apparatus in another view of y-z plane;

FIG. 3 illustrates an example in which deposition is being performed in the deposition apparatus of FIG. 2;

FIGS. 4A and 4B illustrate an example in which a deposition incident angle adjusting plate is moved in a first direction or a second direction in the deposition apparatus of FIG. 3;

FIG. 5A is a perspective view of a deposition apparatus, according to another embodiment of the present invention;

FIG. 5B is a plan view illustrating a top view of the deposition apparatus of FIG. 5A;

FIG. 6 illustrates an example in which a deposition material sprayed from a nozzle of a deposition source passes through a deposition incident angle adjusting plate and is deposited on a substrate;

FIGS. 7A, 7B, and 7C illustrate deposition profiles of the deposition material deposited by the deposition apparatus in which the deposition incident angle adjusting plate is fixed, according to comparative examples;

FIG. 8 illustrates a deposition profile of the deposition material deposited by the deposition apparatus when the deposition incident angle adjusting plate is moved, according to a test of the present embodiment; and

FIG. 9 illustrates a deposition apparatus, according to another embodiment of the present invention.

### DETAILED DESCRIPTION OF THE INVENTION

As the invention allows for various changes and numerous embodiments, particular embodiments will be illustrated in the drawings and described in detail in the written description. Effects and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein.

Hereinafter, one or more embodiments of the present invention will be described below in more detail with reference to the accompanying drawings. Those components that are the same or are in correspondence are rendered the same reference numeral regardless of the figure number, and redundant explanations are omitted.

Hereinafter, in one or more embodiments, while such terms as “first,” “second,” etc., may be used, but such components must not be limited to the above terms, and the above terms are used only to distinguish one component from another.

Hereinafter, in one or more embodiments, a singular form may include plural forms, unless there is a particular description contrary thereto.

Hereinafter, in one or more embodiments, terms such as “comprise” or “comprising” are used to specify existence of a recited feature or component, not excluding the existence of one or more other recited features or one or more other components.

Hereinafter, in one or more embodiments, it will also be understood that when an element such as layer, region, or component is referred to as being “on” another element, it can be directly on the other element, or intervening elements such as layer, region, or component may also be interposed therebetween.

In the drawings, for convenience of description, the sizes of layers and regions are exaggerated for clarity. For example, a size and thickness of each element may be random for convenience of description, thus, one or more embodiments of the present invention are not limited thereto.

Expressions such as “at least one of,” when preceding a list of elements, modify the entire list of elements and do not modify the individual elements of the list.

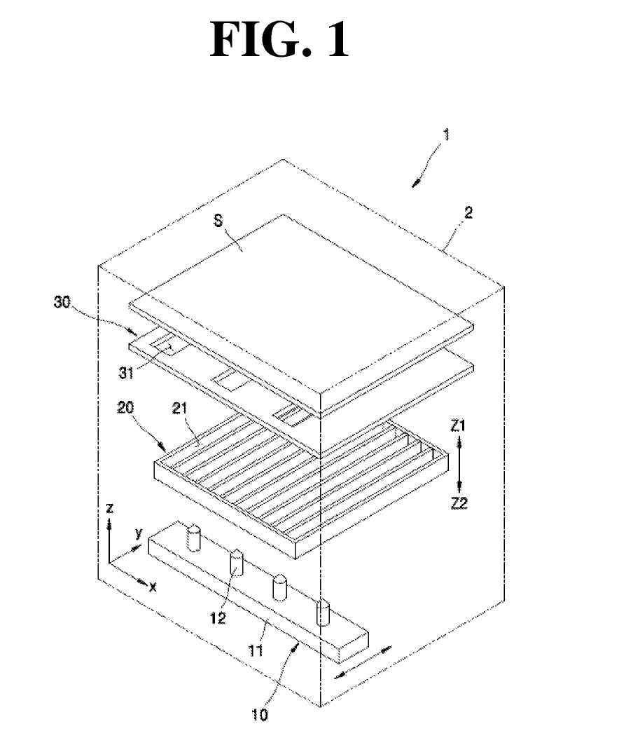

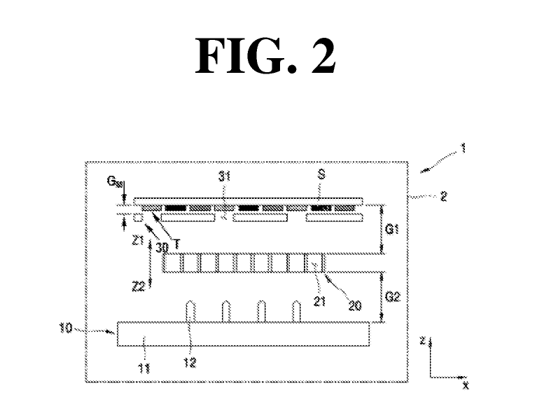

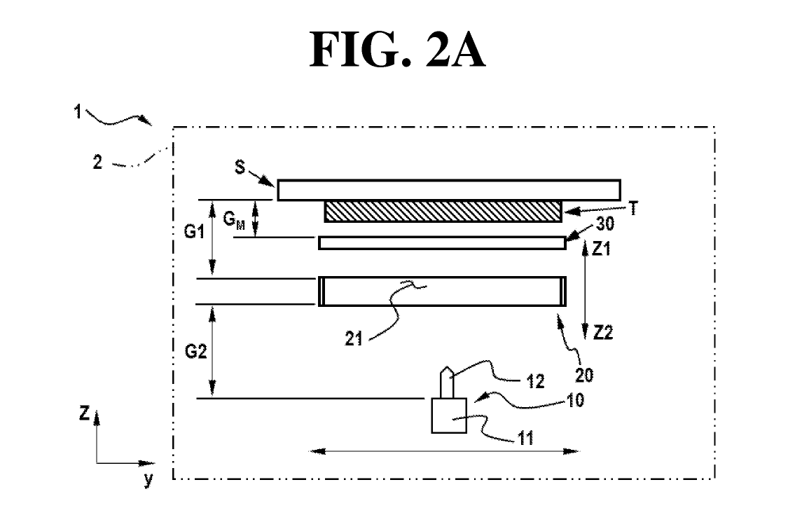

FIG. 1 is a perspective view of a deposition apparatus 1 according to an embodiment of the present invention. FIGS. 2 and 2A illustrate the deposition apparatus 1 of FIG. 1.

Referring to FIGS. 1 and 2, the deposition apparatus 1 may include a vacuum chamber 2, a deposition source 10, a deposition incident angle adjusting plate 20, a mask 30, and a substrate S. The mask 30 is separated from the substrate S by a gap GM. The deposition incident angle adjusting plate 20 is spaced apart from the nozzles 12.

The vacuum chamber 2 is maintained in a high vacuum state and provides an environment appropriate for a deposition procedure. For example, the inner space of the vacuum chamber 2 may be maintained at a pressure of about 10⁻⁶ Torr or less.

The deposition source 10 may include a crucible 11 that is filled with a deposition material, and a plurality of nozzles 12 for spraying the deposition material that is evaporated in the crucible 11. The deposition source 10 may further include a heater (not shown) for evaporating the deposition material in the crucible 11.

The deposition material may be an organic material for forming an organic emission layer. However, the type of the deposition material is not limited thereto and the deposition material may be a metal material.

The nozzles 12 are arranged to be separated from each other. For example, the nozzles 12 may be linearly arrayed. In more detail, the nozzles 12 may be linearly arrayed along an x-axis direction that is perpendicular to a first direction (i.e., Z1) toward the substrate S.

The deposition source 10 may be moved in a direction that crosses (e.g., the direction (i.e., a y-axis direction) that is perpendicular to) the x-axis direction in which the nozzles 12 are arrayed. The movement direction (i.e., the y-axis direction) of the deposition source 10 is perpendicular to the first direction (i.e., Z1) that is toward the substrate S.

The substrate S may be disposed above the deposition source 10 to be separated from the deposition source 10. Also, the substrate S may be disposed so as to face the nozzles 12. The deposition material that is sprayed from the nozzles 12 may be deposited on the substrate S so that a thin-film T may be formed on the substrate S.

The mask 30 is disposed between the deposition source 10 and the substrate S. The mask 30 is disposed adjacent to the substrate S. The mask 30 includes first openings 31 that have a predetermined pattern. The pattern of the first openings 31 may correspond to a pattern of the thin-film T to be deposited on the substrate S. Therefore, as the deposition material passes through the first openings 31 of the mask 30, the thin-film T having the pattern that corresponds to the pattern of the first openings 31 may be deposited on the substrate S.

The mask 30 may be formed of one of a group of materials consisting of metal, inorganic material such as glass, organic material such as polymer, and a combination of said materials; but a material of the mask 30 is not limited thereto.

At least one deposition incident angle adjusting plate 20 is disposed between the mask 30 and the deposition source 10. The deposition incident angle adjusting plate 20 is disposed above the nozzles 12 with a space therebetween. Since the deposition incident angle adjusting plate 20 is separated from the nozzles 12, the deposition incident angle adjusting plate 20 is not affected by a temperature of the nozzles 12. Thus, a material for manufacturing the deposition incident angle adjusting plate 20 may be easily selected.

The deposition incident angle adjusting plate 20 includes a plurality of second openings 21 for adjusting the deposition angle of the deposition material with respect to the substrate S.

The second openings 21 may extend in a direction (i.e., a z-axis direction) that is parallel to the first direction (i.e., Z1) toward the substrate S. Accordingly, from among the deposition material that is sprayed from the nozzles 12, the deposition material sprayed with a relatively great incident angle with respect to the substrate S passes through the second openings 21. Whereas the deposition material sprayed with a relatively small incident angle with respect to the substrate S is reflected by the second openings 21, thus, the incident angle of the deposition material deposited on the substrate S may be changed.

Also, the second openings 21 may extend in a direction that is parallel to the movement direction (i.e., the y-axis direction) of the deposition source 10. In addition, a shape of surfaces of the second openings 21 in a direction (i.e., surfaces in X and Y-axes directions) that is perpendicular to the first direction (i.e., Z1) may vary. For example, although not illustrated, the shape of the second openings 21 may be a polygonal shape including a square or a regular hexagon or may be a shape of which portion is curved.

The deposition incident angle adjusting plate 20 may be movable in the first direction (i.e., Z1) toward the substrate S and in a second direction (i.e., Z2) opposite the first direction (i.e., Z1). Accordingly, the uniformity of the thin-film T formed on the substrate S may be improved. This will be described later.

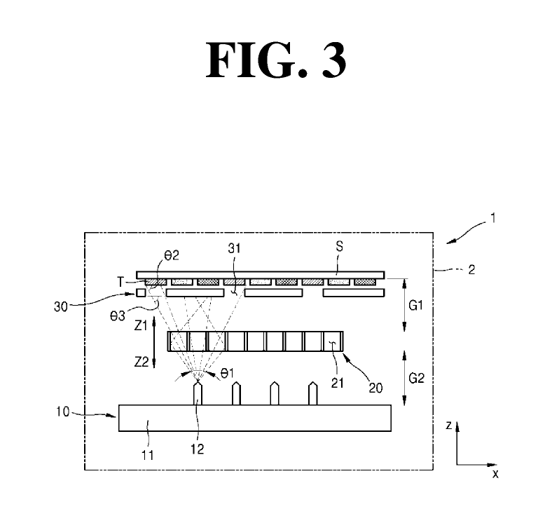

FIG. 3 illustrates an example of deposition is performed in the deposition apparatus 1 of FIG. 2. For convenience of description, FIG. 3 depicts a case when the deposition material is sprayed only from one of the nozzles from among the nozzles 12, but one or more embodiments are not limited thereto, and the deposition material may be sprayed from all of the nozzles 12.

Referring to FIG. 3, the nozzle 12 of the deposition source 10 sprays the deposition material. In more detail, the deposition source 10 sprays the deposition material at a predetermined spraying angle θ1.

A movement of the deposition material sprayed from the nozzle 12 may be guided by the second openings 21 of the deposition incident angle adjusting plate 20. Accordingly, part of the deposition material that is sprayed from the nozzle 12 may have a different incident angle θ2 with respect to the substrate S.

For example, part of the deposition material that is sprayed from the nozzle 12 and has a great incident angle θ2 with respect to the substrate S may pass through the second opening 21, whereas an incident angle of part of the deposition material that is sprayed from the nozzle 12 and has a small incident angle θ2 with respect to the substrate S may change deposition incident angle while the deposition material passes through the second opening 21 because, if the incident angle θ2 of the deposition material is small, the deposition material may hit a wall of the second opening 21.

However, since the incident angle θ2 of the deposition material with respect to the substrate S is changed by the deposition incident angle adjusting plate 20, a minimum incident angle θ3 of the deposition material with respect to the first opening 31 of the mask 30 may be achieved. The minimum incident angle θ3 is equal to or greater than a predetermined angle. For example, the minimum incident angle θ3 may be equal to or greater than 60 degrees.

The deposition material that is incident on the first opening 31 of the mask 30 passes through the first opening 31 and is deposited on a region of the substrate S that overlaps the first opening 31. Accordingly, the thin-film T having the pattern that corresponds to the first opening 31 is formed on the substrate S. Since the minimum incident angle θ3 of the deposition material with respect to the first opening 31 is increased, it is possible to sharply decrease the occurrence of a shadow phenomenon in which the deposition material is deposited on a region of the substrate S that does not overlap the first opening 31 of the mask 30 which is separated from the substrate S.

However, since the deposition incident angle θ2 of the deposition material is changed while the deposition material that is sprayed from the nozzle 12 passes through the second openings 21 of the deposition incident angle adjusting plate 20, the deposition material may be deposited more on some regions of the mask 30 and may be deposited less on other regions of the mask 30. Accordingly, the uniformity of the thin-film T for by the deposition material that passed through the first opening 31 of the mask 30 and is deposited on the substrate S may deteriorate.

In the present embodiment, the deposition incident angle adjusting plate 20 is movable in the first direction (i.e., Z1) and the second direction (i.e., Z2), so that it is possible to prevent the uniformity of the thin-film T from deteriorating if the deposition incident angle adjusting plate 20 is fixed.

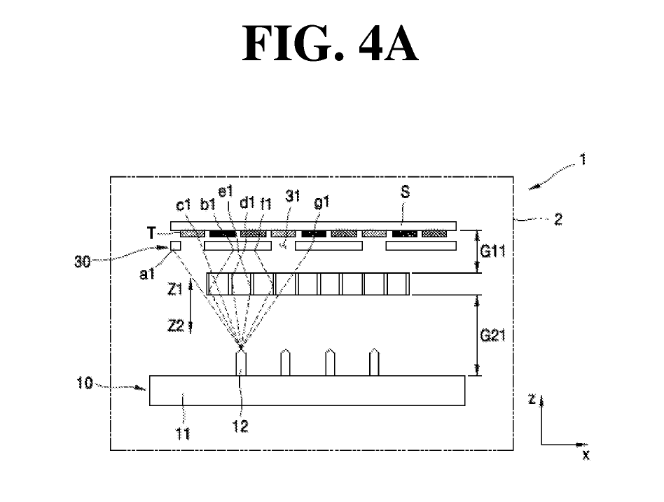

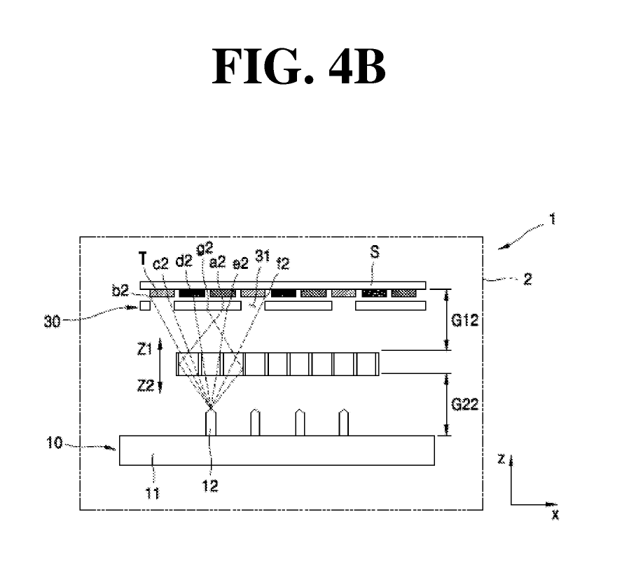

FIGS. 4A and 4B illustrate an example in which the deposition incident angle adjusting plate 20 is moved in the first direction (i.e., Z1) or the second direction (i.e., Z2) in the deposition apparatus 1 of FIG. 3.

Referring to FIG. 4A, the deposition incident angle adjusting plate 20 is moved in the first direction (i.e., Z1) and thus is located at a first position. Accordingly, a distance between the deposition incident angle adjusting plate 20 and the substrate S is decreased from G1 to G11, and a distance between the deposition incident angle adjusting plate 20 and the nozzle 12 is increased from G2 to G21. In this case, the deposition material that passed through the deposition incident angle adjusting plate 20 may be concentrated on points a1, b1, c1, d1, e1, f1, and g1 of the substrate S or the mask 30.

Referring to FIG. 4B, the deposition incident angle adjusting plate 20 is moved in the second direction (i.e., Z2) and thus is located at a second position. Accordingly, the distance between the deposition incident angle adjusting plate 20 and the substrate S is increased from G1 to G12, and the distance between the deposition incident angle adjusting plate 20 and the nozzle 12 is decreased from G2 to G22. In this case, the deposition material that passed through the deposition incident angle adjusting plate 20 may be concentrated on points a2, b2, c2, d2, e2, f2, and g2 of the substrate S or the mask 30. Some of the points a2, b2, c2, d2, e2, f2, and g2 may be different from points a1, b1, the c1, d1, e1, f1, and g1.

As described above, since the deposition incident angle adjusting plate 20 is moved in at least one of the first direction (i.e., Z1) and the second direction (i.e., Z2), the deposition material that is sprayed from the nozzle 12 and passes through the second opening 21 of the deposition incident angle adjusting plate 20 may reach different regions of the substrate S and different regions of the mask 30. Therefore, it is possible to prevent a phenomenon in which the deposition material is concentrated on some regions because the deposition incident angle adjusting plate 20 is fixed. By doing so, the uniformity of the thin-film T formed on the substrate S by the deposition material that passed through the mask 30 may be improved.

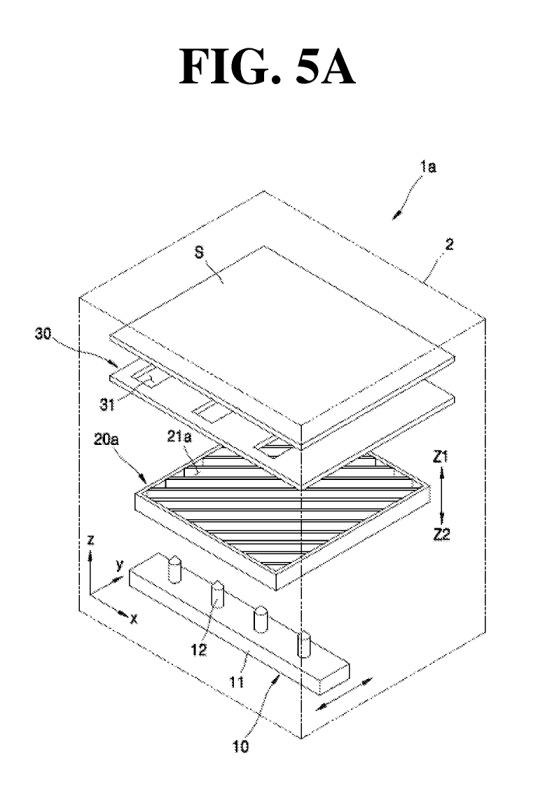

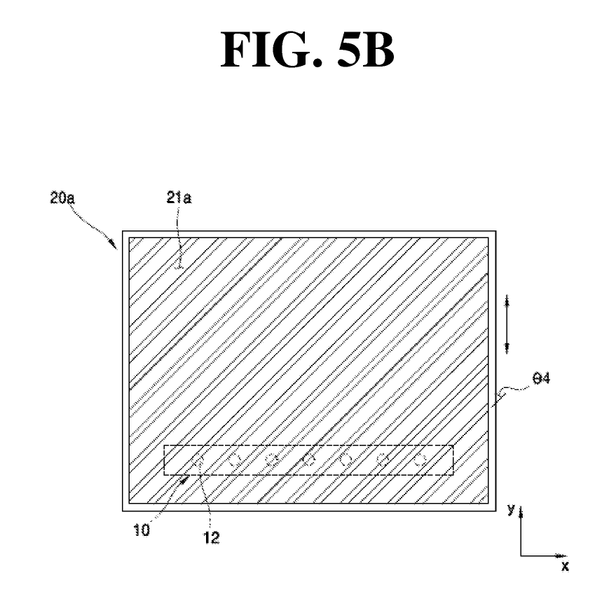

FIG. 5A is a perspective view of a deposition apparatus 1a, according to another embodiment of the present invention. FIG. 5B is a plan view illustrating a top view of the deposition apparatus 1a of FIG. 5A. For convenience of description, FIG. 5B does not illustrate a substrate S and a mask 30.

Referring to FIGS. 5A and 5B, the deposition apparatus 1a may include a vacuum chamber 2, a deposition source 10, a deposition incident angle adjusting plate 20a, the mask 30, and the substrate S.

The vacuum chamber 2, the deposition source 10, the mask 30, and the substrate S are the same as those described in the previous embodiment, thus, differences therebetween are mainly described.

The deposition source 10 is arranged by arraying a plurality of nozzles 12 in a predetermined direction. The deposition source 10 may be moved in a direction that crosses an array direction of the nozzles 12. For example, the deposition source 10 may be moved in a direction that is perpendicular to the array direction of the nozzles 12.

A plurality of second openings 21a of the deposition incident angle adjusting plate 20a may extend in a direction that forms an acute angle with a movement direction of the deposition source 10. That is, an angle θ4 formed between an extending direction of the deposition source 10 and the movement direction of the deposition source 10 may be the acute angle. When the deposition source 10 is moved, a shape of the second openings 21a that overlap the nozzles 12 varies, so that a deposition region on the substrate S may vary.

Since the deposition incident angle adjusting plate 20a is moved in at least one of a first direction (i.e., Z1) and a second direction (i.e., Z2), it is possible to secondly prevent the occurrence of a phenomenon in which the deposition material is concentrated on some regions.

In other words, since the extending direction of the second openings 21a of the deposition incident angle adjusting plate 20a is changed, the concentration of the deposition material on some portions of the substrate S may be firstly prevented and the deposition source 10 and also, according to a relative movement of the deposition incident angle adjusting plate 20a and the substrate S, the concentration of the deposition material may be secondarily prevented. As a result, the uniformity of the thin-film T formed on the substrate S via the deposition material that passes through the mask 30 may be further improved.

Due to the deposition incident angle adjusting plate 20a that extends so as to allow the second openings 21a to make an acute angle, e.g., 45 degrees, with the movement direction of the deposition source 10, the uniformity of the thin-film T may be improved by 92%, and since the deposition incident angle adjusting plate 20a is moved in the first direction (i.e., Z1) and the second direction (i.e., Z2), the uniformity of the thin-film T may be improved by 97.12%.

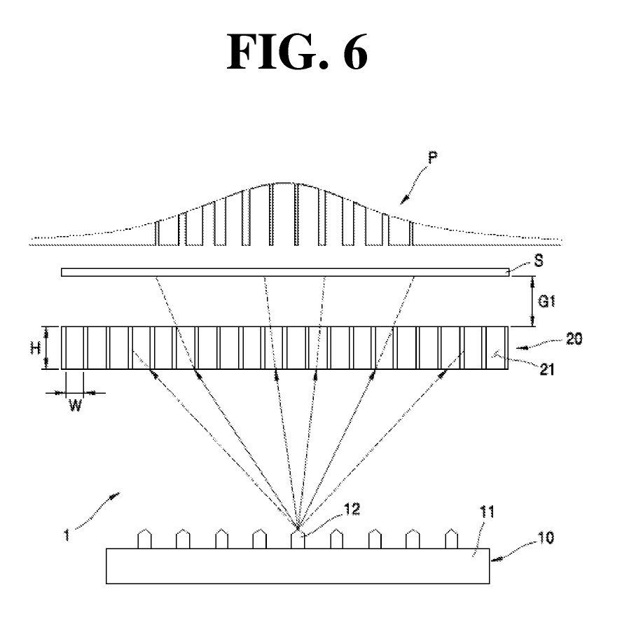

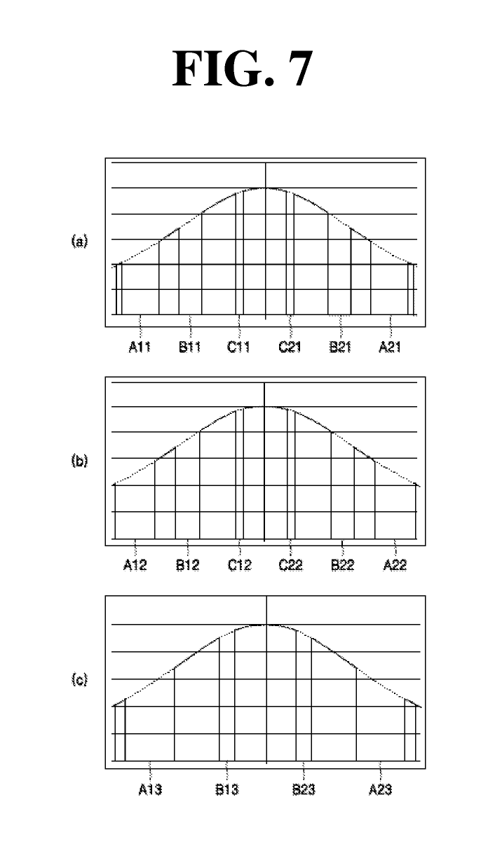

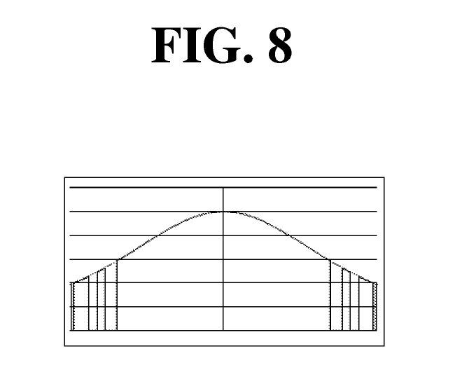

FIG. 6 illustrates an example when a deposition material that is sprayed from a nozzle 12 of a deposition source 10 passes through a deposition incident angle adjusting plate 20 and is deposited on a substrate S. FIGS. 7A, 7B, 7C, and 8 illustrate simulation results according to the deposition apparatus 1 of the FIG. 6. FIGS. 7A, 7B, 7C illustrate deposition profiles of the deposition material deposited by the deposition apparatus 1 when the deposition incident angle adjusting plate 20 is fixed, according to the comparative examples, and FIG. 8 illustrates a deposition profile of the deposition material deposited by the deposition apparatus 1 when the deposition incident angle adjusting plate 20 is moved, according to a test of the present embodiment.

Referring to FIG. 6, as a common condition for the simulations in the comparative examples of FIGS. 7A, 7B, and 7C and the present embodiment, the deposition apparatus 1 includes the deposition source 10 that faces the substrate S, and the deposition incident angle adjusting plate 20 that is disposed between the substrate S and the deposition source 10. A height H of second openings 21 of the deposition incident angle adjusting plate 20 was 50 mm, a width W of the second openings 21 was 50 mm, and the deposition material was sprayed from a nozzle 12 from among a plurality of nozzles 12 of the deposition source 10. In order to clearly shown an effect on the deposition material due to the deposition incident angle adjusting plate 20, the mask 30 was excluded from the deposition apparatus 1.

After setting the aforementioned conditions, when the deposition material was sprayed, a deposition profile P was formed on the substrate S.

In the comparative examples of FIGS. 7A, 7B, and 7C, the deposition incident angle adjusting plate 20 was fixed, a distance G1 between the substrate S and the deposition incident angle adjusting plate 20 was fixed at 50 mm, 150 mm, and 200 mm, and then the deposition material was deposited on the substrate S via the deposition incident angle adjusting plate 20.

Referring to FIG. 7A, the deposition material was less deposited on regions A11, B11, C11, A21, B21, and C21, compared to other regions of the substrate S. As a result, the uniformity of a thin-film T formed on the substrate S was 54.348%.

Referring to FIG. 7B, the deposition material was less deposited on regions A12, B12, C12, A22, B22, and C22, compared to other regions of the substrate S. As a result, the uniformity of a thin-film T formed on the substrate S was 52.795%.

Referring to FIG. 7C, the deposition material was less deposited on regions A13, B13, A23, and B23, compared to other regions of the substrate S. As a result, the uniformity of a thin-film T formed on the substrate S was 53.416%.

As apparent from these results, when the deposition incident angle adjusting plate 20 was fixed, i.e., when the distance G1 between the substrate S and the deposition incident angle adjusting plate 20 was fixed, although the distance G1 varied, the uniformity of the thin-film T was considerably low, e.g., the uniformity of the thin-film T was equal to or less than 55%.

FIG. 8 illustrates the test when the substrate S was moved, in more detail, the deposition material was deposited on the substrate S via the deposition incident angle adjusting plate 20 while the deposition incident angle adjusting plate 20 was moved to allow the distance G1 between the substrate S and the deposition incident angle adjusting plate 20 to vary from 50 mm to 200 mm.

Referring to FIG. 8, compared to the comparative examples of FIGS. 7A, 7B, and 7C, the regions on which the deposition material was less deposited were significantly reduced due to the movement of the deposition incident angle adjusting plate 20, and thus the deposition material was deposited in a uniform manner. As a result of the test, the uniformity of the thin-film T was 83.851%.

Hereinafter, a method of depositing a thin-film T of the organic light-emitting display device is described with reference to the above drawings.

Referring to FIG. 3, the substrate S is disposed to face the deposition source 10 that includes the nozzles 12 for spraying the deposition material.

Next, the deposition material that is sprayed from the nozzles 12 is deposited on the substrate S via the second openings 21 of the deposition incident angle adjusting plate 20 and the first openings 31 of the mask 30.

While the deposition material is deposited on the substrate S, the deposition incident angle adjusting plate 20 is moved in the first direction (i.e., Z1) as shown in FIG. 4A or the second direction (i.e., Z2) as shown in FIG. 4B. In this manner, since the deposition incident angle adjusting plate 20 is moved in the first direction (i.e., Z1) or the second direction (i.e., Z2), some regions of the substrate S on which the deposition material is deposited change.

The deposition material that is deposited on the substrate S may be an organic material for forming an organic emission layer to be used in the organic light-emitting display device.

According to the one or more embodiments, the deposition incident angle adjusting plate 20 is moved while the deposition material is deposited on the substrate S, but the one or more embodiments are not limited thereto. For example, the deposition incident angle adjusting plate 20 may be moved before or after the deposition material is deposited on the substrate S.

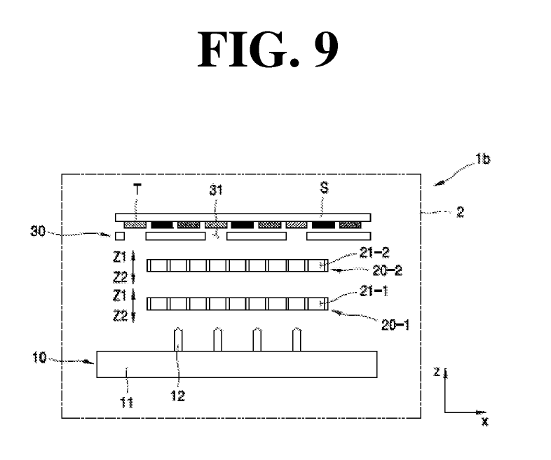

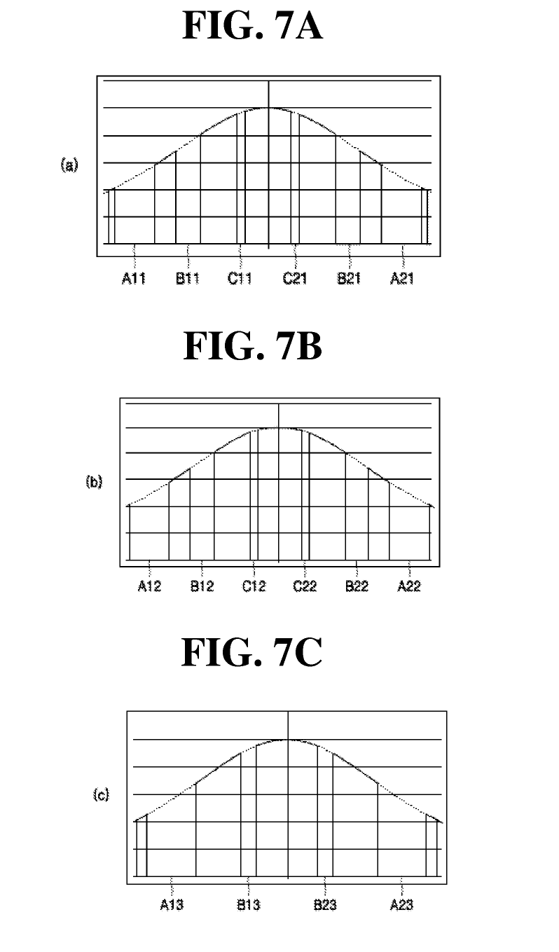

Also, according to the one or more embodiments, one deposition incident angle adjusting plate 20 or 20a is used, but the one or more embodiments are not limited thereto. For example, as shown in FIG. 9, a deposition apparatus 1b may include a plurality of deposition incident angle adjusting plates 20-1 and 20-2. In this regard, the deposition incident angle adjusting plates 20-1 and 20-2 may be moved in one direction or different directions. Also, a shape and a size of second openings 21-1 and 21-2 of the deposition incident angle adjusting plates 20-1 and 20-2 may be constant or at least one of them may be different from the other ones.

As described above with regard to the deposition apparatus and the method of depositing a thin-film of the organic light-emitting display device by using the deposition apparatus according to the one or more of the above embodiments of the present invention, the deposition incident angle adjusting plate for guiding a movement direction of the deposition material sprayed from the deposition source is moved in at least one of a first direction toward the substrate and a second direction opposite the first direction. Accordingly, the uniformity of the thin-film deposited via the deposition incident angle adjusting plate may be improved.

It should be understood that the exemplary embodiments described therein should be considered in a descriptive sense only and not for purposes of limitation. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made therein without departing from the spirit and scope of the present invention as defined by the following claims.

What is claimed is:

1. A deposition apparatus, comprising:
a deposition source comprising a plurality of nozzles that spray a deposition material onto a substrate;
a mask disposed between the substrate and the deposition source and comprising a plurality of first openings through which the deposition material passes; and
at least one deposition incident angle adjusting plate disposed between the mask and the deposition source and comprising a plurality of second openings for adjusting a deposition incident angle of the deposition material that is sprayed from the plurality of nozzles, wherein
the at least one deposition incident angle adjusting plate is movable in a first direction toward the substrate or a second direction opposite the first direction.

2. The deposition apparatus of claim 1, wherein a distance between the substrate and the at least one deposition incident angle adjusting plate varies according to a movement of the at least one deposition incident angle adjusting plate.

3. The deposition apparatus of claim 1, wherein a distance between the deposition source and the at least one deposition incident angle adjusting plate varies according to a movement of the at least one deposition incident angle adjusting plate.

4. The deposition apparatus of claim 1, wherein the plurality of nozzles are linearly arrayed in a direction that is perpendicular to the first direction.

5. The deposition apparatus of claim 4, wherein the deposition source is moved in a direction that is perpendicular to the first direction and crosses the direction in which the plurality of nozzles are arrayed.

6. The deposition apparatus of claim 5, wherein the plurality of second openings extend in a direction that is in parallel with a movement direction of the deposition source.

7. The deposition apparatus of claim 5, wherein the plurality of second openings extend in a direction that forms an acute angle with a movement direction of the deposition source.

8. A method of depositing a thin-film of an organic light-emitting display device by using a deposition apparatus, the method comprising:
disposing a substrate to face a deposition source comprising a plurality of nozzles that spray a deposition material;
depositing the deposition material, which are sprayed from the plurality of nozzles, on the substrate via a plurality of second openings of a deposition incident angle adjusting plate and a plurality of first openings of a mask; and
moving the deposition incident angle adjusting plate in at least one of a first direction toward the substrate and a second direction opposite the first direction.

9. The method of claim 8, wherein, one or more regions of the substrate on which the deposition material is deposited vary according to a movement of the deposition incident angle adjusting plate.

10. The method of claim 8, wherein the deposition material comprises an organic material for forming an organic emission layer.

11. The method of claim 8, wherein the deposition material further comprises a metal material.

12. The deposition apparatus of claim 1, wherein the deposition material further comprises a metal material.

13. The method of claim 8, wherein the mask is separated from the substrate.

14. The deposition apparatus of claim 1, wherein the mask is separated from the substrate.

15. The deposition apparatus of claim 1, wherein the mask is formed of one of a group of materials consisting of metal, inorganic material, organic material, and a combination of said materials.

16. The method of claim 8, wherein the mask is formed of one of a group of materials consisting of metal, inorganic material, organic material, and a combination of said materials.
